(19) United States
(12) Patent Application Publication
(10) Pub. No.: US 2022/0235780 A1
(43) Pub. Date: Jul. 28, 2022

(54) Self-Powered Thermal Fan

(71) Applicant: Randall H. Reid, Burlington, Ontario (CA)

(72) Inventor: Randall H. Reid, Burlington, Ontario (CA)

(21) Appl. No.: 17/594,385

(22) PCT Filed: Apr. 22, 2020
(86) PCT No.: PCT/CA2020/050530

§ 371 Date: Oct. 14, 2021

Related U.S. Application Data
(60) Provisional application No. 62/838,604, filed on Apr. 25, 2019.

(51) Int. Cl. F04D 25/06; F04D 19/00; H01L 35/30; H01L 35/32

(52) U.S. Cl. CPC F04D 25/06; H01L 35/32; H01L 35/30; F04D 19/002

(57) ABSTRACT

A self-powered thermal fan for circulating air for use in cooperation with a heat source, such as a wood stove, and which relies on a thermoelectric generator to provide electrical current to power a motor. The motor is used to move fan blades which create a warm air flow away for the heat source, and a cooler air flow towards the fan assembly. In the present invention, the fan assembly includes at least two thermoelectric generator modules that are separate by a gap which allows for increase module surface area, without creating a risk of module damage caused by heat expansion. The improved design also preferably includes the use of angled module mounting lands, which aid in increasing heat gradient across the module. Additionally, the present device provides the ability to have larger heat exchange surfaces that can provide increased cooling to the opposite surfaces of the thermoelectric generator module. Improved output and efficiencies of the self-powered thermal fan assembly are achieved.

### FIELD OF THE INVENTION

The present invention relates to heat transfer fans, and in particular, self-powered thermal fans for use in conjunction with heated surfaces, such as fossil-fuel burning stoves.

### BACKGROUND OF THE INVENTION

Heating units such as wood stoves, and other fossil-fuel combustible material burning stoves, hot water radiators, gas fireplaces, electrical heaters, and the like, disseminate heat into the surrounding space both by radiation and by convection of thermal air currents circulating around the unit. Warm air distribution from the unit may be enhanced by means of an air blower or fan suitably placed on, or adjacent to, the unit. Typically, these air circulating fans are powered by an electric battery or by electrical mains power supply.

In accordance with the so-called “Peltier Effect”, it is known though that when a direct electric current is passed through a thermoelectric couple, heat will be absorbed at one end of the couple, to cause cooling thereof, and heat will be generated at the other end of the couple, and thereby cause a rise in temperature. By reversing the current flow, the direction of heat flow will be reversed.

In a similar, but reverse manner to the Peltier Effect, by the so-called “Seebeck Thermocouple Effect”, a thermoelectric generator will generate an electric potential across its terminals if a temperature gradient, or thermocline, is provided across the thermoelectric generator module. As a result, electric power is generated by the thermocouple generator module as a function of the temperature difference, or heat gradient, across the module.

Typically, thermoelectric generators are provided in the form of a thermoelectric couple and usually comprise an array of semiconductor couples (P and N pellets) connected electrically in series and thermally in parallel, sandwiched between ceramic or metallized ceramic substrates. Commercial products relying on the Seebeck Effect are known, and include devices such as those available from Tellurex Corporation, who provide a thermoelectric generator which when heated by a propane torch, or the like, will generate electric energy.

U.S. Pat. No. 5,544,488, issued Aug. 13, 1996 and U.S. Pat. No. 7,812,245, issued Oct. 12, 2010, both to the present inventor herein, describe air circulation fans which are powered only by thermoelectric generators that utilize the heat which is available at the heated surface of a heating unit, such as the top of a stove. The devices described therein can provide useful warm air circulation;—notwithstanding the extremely low efficiency of the conversion of thermal energy to electrical energy which is inherent in the aforesaid Seebeck Thermocouple Effect.

In U.S. Pat. No. 5,544,488, a fan is placed above the thermoelectric generator module and electrical power from the module is use to turn the fan. As a result, warm air propelled forward from the unit to provide warm air circulation. In addition, incoming cooler air is pulled inward to the fan unit, and this cooler air acts to enhance the cooling of a heat sink cool end. This provides increased electrical current output, and reduces the heat applied to the hot end of the thermoelectric generator module.

In U.S. Pat. No. 7,812,245, an improved version of this device is provided wherein the fan motor component is located in a motor-receiving cavity located in a portion of the lower heat transfer member, so that the fan motor is located below the thermoelectric generator module. The thermoelectric generator structure is located between the lower heat transfer member, and an upper heat transfer member above the thermoelectric generator. The device is of suitable material, size, mass and shape, so as to provide an enhanced temperature gradient between the thermocouple structure and the heat source. This allows for sufficient heat transfer from the first heat transfer member to the thermoelectric generator module, in order to generate the requisite power to effect rotation of the fan motor, and thus, the fan blades.

While these self-powered fan devices have been well received in the industry, there is a desire to provide such self-powered heat transfer fans having improved performance characteristics. In particular, it would be beneficial to the industry to provide Seebeck Thermocouple Effect powered fans for use on heated surfaces, which provide increased airflow while also reducing or minimizing the temperatures observed in the motor and thermoelectric generator areas of the fan.

It should be noted though, that while it might be expected in the art, that increasing the size of the thermoelectric generator module will increase the current generated, increasing the size of the module can lead to damage to the module itself cause by heat expansion across the module, and the like. Also, increasing the thermoelectric generator module size, can negatively impact the efficiency of the device.

To address these issues, it would be advantageous to the industry to provide a self-powered thermal fan for use on a heated surface, by application of the Seebeck Thermocouple Effect, which would provide increased power output. It would also be beneficial if this approach also provided increased airflow created by the fan. This combined effect would provide greater fan efficiency, while also preferably aiding in reducing the temperatures observed in the motor and thermoelectric generator areas of the fan.

### SUMMARY OF THE INVENTION

It is an advantage of the present invention to provide an improved self-powered air circulation fan which generates its own electrical power from a temperature difference, or heat gradient, induced across distinct members of the fan.

It is a further advantage of the present invention to provide an improved self-powered air circulation fan which generates its own electrical power from an external heat source for use with such heat source, for example a fossil-fuel burning stove.

It is a yet further advantage of the present invention to provide an improved self-powered air circulation fan having a heat transfer feature which is at least partially cooled by the cooling assistance of the fan blades.

It is a still further advantage of the present invention to provide an improved self-powered air circulation fan with improved efficiency, and improved resistance to heat-related damage to the fan and circulation motor.

The advantages set out hereinabove, as well as other objects and goals inherent thereto, are at least partially or fully provided by the self-powered thermal fan of the present invention, as set out herein below.

Accordingly, in a first aspect, the present invention provides a self-powered fan assembly for circulating air around a heating source, said fan assembly comprising:

a heat transfer stem thermally, and preferably also physically, connected at a proximate end thereof with said heat source;

at least two heat transfer surface-containing arms connected to a distal end of said heat transfer stem;

module lands at each of the at least two arms so that each of said module lands are thermally connected to said arms, and thereby, to said heat transfer stem;

a gap defined between said module lands;

an electric motor to act as a fan motor which electric motor is preferably attached to said fan assembly in an area between the at least two arms;

fan blades attached to said fan motor which blades are moved by said electric motor, and which operably create a warm air flow away from said fan, and a cooler air flow toward said fan;

at least two thermoelectric generator modules wherein each of said thermoelectric generator modules are individually thermally connected on a first surface to said module lands; and

a heat exchange structure which is thermally connected to a second, opposite surface of each of said thermoelectric generator modules, and preferably having at least two heat exchange structures, each of which is attached to one of said second, opposite surfaces of said thermoelectric generator modules,

whereby a heat gradient is created across each of the thermoelectric generator modules so as to generate electric power from each of said thermoelectric generator modules, and thereby power said fan motor.

The heat transfer stem and arms, are preferably generally planar in nature. The stem is thermally, and preferably physically, connected at a first proximate end to the heat source. In one embodiment, the heat transfer stem includes a base attached to the proximate end which base is adapted to rest on a heat source. The base rests on a flat surface located at or near the top of the stove. In another embodiment, the heat transfer stem is formed as part of the heat source, and thus, the proximate end of the heat transfer stem is formed as part of, or directly attached to, a preferably flat surface at or near the top of the stove.

The heat transfer stem and arms preferably form a “Y” shaped device, with the lower end of stem part of the “Y” being the proximate end which is connected to the base, or to the heat source. The two upper ends of the Y-shaped heat transfer stem are the arms which act as heat transfer surface-containing areas. The overall length of the heat transfer stem is chosen so as to be sufficient as to provide a suitable temperature to the thermoelectric generator, so as to effect blade rotation, without incurring damage of the thermoelectric generator or motor, by overheating. Typically, the stem is between 5 and 30 cm in length.

The ends of the arms are attached at one end to the heat transfer stem, and at the other end, each are connected to separate module lands. The lands are preferably separated one from the other with a gap between them, in order to avoid mechanical damage caused by thermal expansion of the module and/or module lands. In one preferred embodiment, the fan assembly includes two module lands, at the ends of each of two arms.

Each module land preferably includes a flat surface to which a thermoelectric generator module is thermally and physically attached. The module lands can be placed so as to be coplanar with one another and parallel to the heat source during use. As such, they can be located at the same level and in a side-by-side arrangement with each other. Alternatively, the module lands can be angled with respect to each other, and/or to the heat source surface. Preferably, in this embodiment, the module lands are placed at an angle of between 60° and 150° with respect to each other. More preferably, the module lands are placed at an angle of between 90° and 135°, and most preferably, at an angle of between 100° and 120°, with respect to each other. In one preferred embodiment, the angles of the two module lands are also in equal, but opposite directions, with respect to the heat transfer arms or stem, so that the module lands are positioned symmetrically across the device, and angled towards each other.

The thermoelectric generator modules are any suitable devices which can be used to generate an electrical current resulting from the heat gradient across the modules. These types of modules are known in the art, and typically and preferably rely on the Seebeck Thermocouple Effect. Commonly, the thermoelectric generator modules are square or rectangular in shape, and are generally 0.5-5 cm thick. They typically have flat ceramic or metallized ceramic surfaces on their two opposite surfaces. Power is derived in the thermoelectric generator module, in a known manner, by preferably utilizing an array of thermocouples. Normally, the current is generated from the thermoelectric generators, and supplied to the electric motor as a direct current (DC).

One of the flat surfaces of the thermoelectric generator module is attached to, and thermally connected to the module land so that heat from each of the arms is directed to one side of the thermoelectric generator modules. The opposite flat surface of each of the modules is attached to a heat exchange structure, which structure can have any suitable size or shape. A single heat exchange structure can be connected to any, or all, or the thermoelectric generators, but preferably, a separate heat exchange structure is attached to each thermoelectric generator module. In either arrangement, the heat exchange structure is thermally connected to the opposite side of the thermoelectric generator modules, and thereby acts to dissipate heat from the two, or more, modules.

As a result, this arrangement provides at least two thermoelectric generator modules, each of which has an observed temperature gradient across the thermoelectric generator modules, and thus, the combined thermoelectric generator modules create and/or increase the electrical current generated over prior art devices.

As is known in the art, an electrical current is thus produced by the temperature gradient, or thermocline, across the thermoelectric generator module, and it is this current which is supplied to the fan motor in order to rotate the motor, and thus, move the fan blades and create air flow. Movement of the fan blades acts to circulate and force warm air outwards from the heating unit, and also draw cool air from behind the heat source, or above the heat source, which is then drawn through the heat exchanger. This overall effect acts to force warm air outwards from the top of the heat source, while drawing cooler air through the heat exchanger surfaces.

The fan preferably draws all of its power from the thermoelectric generator modules, and thus requires no external electrical power source. As a consequence of this arrangement, the fan stops, starts and runs automatically depending on the temperature of the heated surface. The fan also provides variable air circulation in proportion to the amount of heat provided to the hot side heat exchanger base and resultant thermocline, or heat gradient, across the thermoelectric generator.

The two or more thermoelectric generator modules can be wired, or otherwise electrically connected, in parallel, in order to increase the current provided by the two or more modules. More preferably however, the various modules are wired, or otherwise electrically connected in series, in order to increase the voltage provided by the two or more modules. This second approach can be beneficial in situations where the thermocline gradient across the various modules differs so that electrical output from the modules varies between the modules.

Placement of the fan motor can vary within the fan assembly. Preferably however, an area is provided between two inwardly curving arms, attached to the heat transfer stem, in a generally Y-shaped device. This creates a motor-receiving cavity which houses said fan motor, in an area below, or between, the thermoelectric generators. The fan motor is connected to fan blades, in a manner similar to the known prior art devices. The shape of the fan blades can vary in order to provide sufficient air movement for the electrical current generated.

Fans according to the present invention, can typically provide satisfactory air circulation at temperature gradients across the thermoelectric generator of as low as, for example, 30° C.

By suitable selection of material and the surface area, size, mass and shape of the heat transfer stem, and the heat exchange structure, suitable temperature gradients across the thermoelectric generators can be obtained to allow sufficient heat to reach the module without destroying it, and create a sufficient heat gradient large enough to generate sufficient power to effect rotation of the fan blades. Such suitable determination of material, surface area, size, mass and shape may be readily determined by the skilled person in the art.

Moreover, by use of the design features of the embodiment shown in U.S. Pat. No. 7,812,245, the fan blades are, preferably, oriented relative to the module lands so as to cause a portion of the ambient air flow to be drawn past the module lands, and thus provide a partial cooling effect on the module lands, and the fan motor. However, this cooling effect is typically less than the cooling effect provided by the heat exchange structures. However, this approach also aids in optimizing or maximizing the temperature gradient across the thermoelectric generator modules. As will be understood by the skilled artisan, the greater the increase in temperature of the heated base or stem, the greater the power generated with commensurate fan speed. Increased fan speed causes faster air flow around the fan and base to enhance cooling of the fan motor and thermoelectric generator. Thus, this cooling effect constitutes a useful safety feature in that it limits the heat exposure of the fan motor and the thermoelectric generator.

Preferably, the axis of rotation of the fan is angularly displaced,—most preferably perpendicularly, with respect to the surfaces of the thermoelectric generator module and the heat exchange structure.

Typically, the heat exchange structures comprise a plurality of cooling vanes which dissipate heat from the upper surface of the thermoelectric generator. As indicated above, all of the thermoelectric generators can be attached to a single heat exchange structure. Preferably however, each thermoelectric generators is individually attached to a separate heat exchanger structure. The size and shape of the heat exchange structures can vary depending on the application efficiency, or based on a desired visual appearance.

It is also highly desirable that the vanes of the heat exchange structure are disposed relative to the fan blades so that the vanes extend through the cool air stream generated by the rotation of the fan blades. In one embodiment according to the invention the cooling vanes are so disposed having one vane located next to another so as to take the form of a fan-shaped array. Thus, the fan blades are shaped and located relative to the module and heat exchange structure so as to cause cooler air to pass adjacent to and/or through the heat exchanger by rotation of the fan blades.

The heat transfer stem, base, arms, module lands, heat exchanger structures, and fan blades of the fan of the present invention, may all be formed of any suitable material, which can withstand the heat of the surrounding environment. This preferably includes materials such as metals or metal alloy such as, for example of aluminum, steel, copper and iron, or combinations thereof. The fan blades may also be positioned within a protective wire frame or shroud to prevent physical injury.

The heat source can be any heat source including fossil fuel burning devices such as coal, oil or wood burning stoves, or stoves which operate by combustion of combustible gases (preferably methane, propane or butane). Stoves which burn wood-based materials (such as wood pellets, and the like) might also be used.

As indicated above, in one exemplary implementation of the fan assembly of the present invention, the fan assembly includes a thermally conductive base which allows the fan assembly to be placed on the heated surface of a heat source. In an alternative embodiment however, the fan assembly is formed as part of the heat source, so that a base is not required.

As such, in a further aspect, the present invention also provides a heat source, such as a wood stove or the like, which heat source comprises a heated surface, and a fan assembly according to the present invention, which fan assembly includes a heat transfer stem which has a proximate end which is formed into or permanently attached to said heat source.

### DETAILED DESCRIPTION OF THE INVENTION

The present application is primarily directed to the use of thermoelectric generators to generate electrical current to power a fan assembly, when using the fan assembly in combination with a heat source. Preferably, the heat source is a wood stove, or the like. However, the skilled artisan will be aware that the fan assemblies of the present invention can be used in a wide variety of application. Accordingly, while the present application is hereinafter described with particular reference to wood stoves, and the like, the skilled artisan will be well aware that the present application is equally applicable in other applications.

### BRIEF DESCRIPTION OF THE DRAWINGS

Embodiments of this invention will now be described by way of example only in association with the accompanying drawings in which:

FIG. 1 is an isometric view of a prior art device according to U.S. Pat. No. 5,544,488;

FIGS. 2A and 2B are isometric views of a prior art device according to U.S. Pat. No. 7,812,245;

FIG. 3 is a front, plan view of a first embodiment of the present invention;

FIG. 4 is an isometric view of the device of FIG. 3;

FIG. 5 is a front, plan view of a second embodiment of the present invention;

FIG. 6 is an isometric view of the device of FIG. 5; and

FIG. 7 is a front, plan view of the prior art fan of FIG. 2, which shows the effective cooling area;

FIG. 8 is a front, plan view of the fan of FIG. 5, which shows the effective cooling area; and

FIGS. 9 to 12 are graphs showing relative performance data for the devices of FIGS. 7 and 8.

### DETAILED DESCRIPTION OF THE PREFERRED EMBODIMENTS

The novel features which are believed to be characteristic of the present invention, as to its structure, organization, use and method of operation, together with further objectives and advantages thereof, will be better understood from the following drawings in which a presently preferred embodiment of the invention will now be illustrated by way of example only. In the drawings, like reference numerals depict like elements.

It is expressly understood, however, that the drawings are for the purpose of illustration and description only and are not intended as a definition of the limits of the invention. Also, unless otherwise specifically noted, all of the features described herein may be combined with any of the above aspects, in any combination.

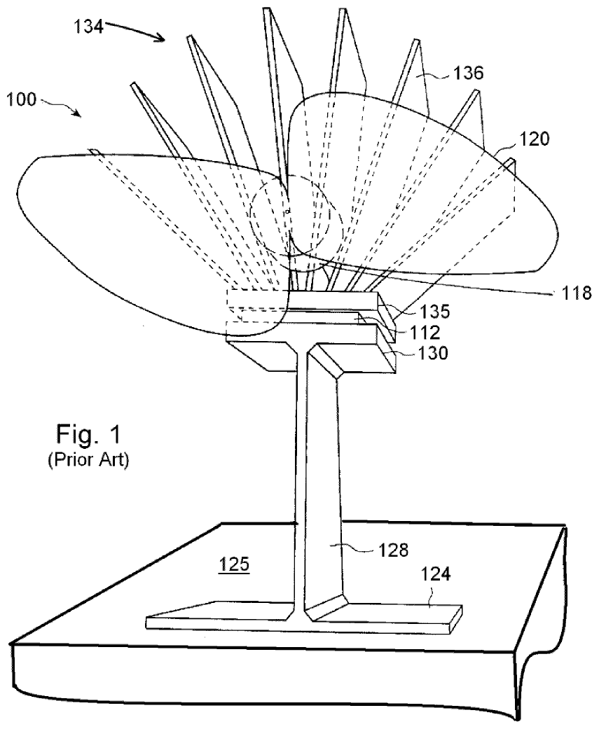

Referring to FIG. 1, a prior art fan assembly 100 of the type described in U.S. Pat. No. 5,544,488 is shown. Fan assembly 100 includes a heat transfer stem 128 connected to a base 124 which rests on the upper surface 125 of a heat source, such as a wood stove (partially shown). At the top end of stem 128 is a single module land 130 on which a single thermoelectric generator module 112 rests. Thermoelectric generator module 112, is comprised of an array of semiconductor couples (P and N pellets) connected electrically in series and thermally in parallel sandwiched between flat metallized ceramic substrates, according to the prior art. A lower surface of module 112 is thermally and physically connected to module land 130, and an upper surface of module 112 is also thermally and physically connected to the lower end 135 of heat exchange structure 134. A plurality of heat exchange vanes 136 are also included as part of heat exchange structure 134, and thereby act to cool the lower end of heat exchange structure 134.

A heat gradient is thereby created across module 112, which heat gradient creates an electrical current. Module 112 has an electrical connection with motor 118 (shown in outline only for clarity), and the electrical current generated by module 112 is used to power motor 118 which in turn, drives fan blades 120.

The mass, size and shape of base 124, and the distance or length and mass of stem 128 between base 124 and module land 130 is such as to provide a suitable heating of the lower side of module 112, while also providing sufficient heat to produce a temperature gradient across module 112, by the cooling effect of heat exchange structure 134. This causes the generation of electrical power in module 112 and thus cause the desired fan rotation. By appropriate design of these components, electrical current can be generated without any damage to module 112 by heat, even when the heated stove surface 125 is heated to temperatures of up to, but preferably not greater than, 500° C.

In the event of a low stovetop temperature, low power generation occurs due to a relatively small thermocline. Thus, fan 100 produces a gentle air circulation that forces heated air forwards, into the area in front of stove 125. The airflow is sufficient to bring cool room temperature air through heat exchange structure 134 to maintain a thermocline across module 112 and produce enough current to maintain an adequate air circulation. In the event of a high stove top temperature, the increase in heat provides more current for fan 100 and the resultant air passing through fan 100 increases greatly. The superheated air from convection is now pushed rapidly across the stovetop, and cool room temperature air flows through the exchanger as in the earlier example, and is also drawn past the module land 130. This latter process is a key feature in the operation of the unit as it strips heat from the module land before it reaches thermoelectric generator module 112, and thus keeps module 112 well within operational tolerances with regard to temperature. Thus, provided that the shape, mass, size and material of composition are considered, efficient cooling of module 112 is provided even for higher stove temperatures.

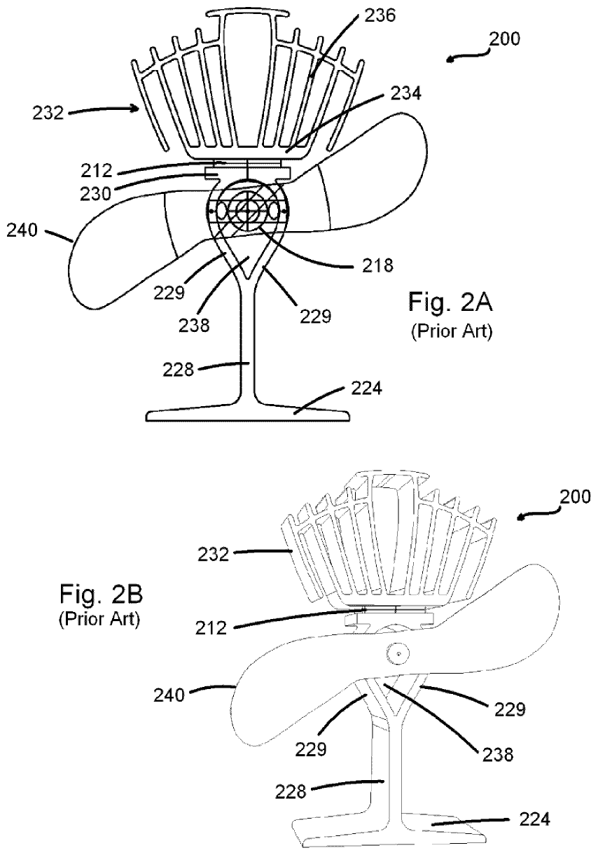

In FIGS. 2A and 2B, a prior art device of the type described in U.S. Pat. No. 7,812,245 is shown. In this approach device 200 has a preferably planar heat transfer stem portion 228 with a base 224 which rests on a stove top (not shown). Stem portion 228 is integrally formed with two arms 229 and an enlarged module land 230. Module land 230 is in thermal communication with the thermoelectric generator module 212. The upper surface of module 212 is in contact with heat exchanger 232 which consists of a lower edge 234 of the heat exchanger 232, and an array of vanes 236.

In this embodiment, base 224, stem 228, arms 229, enlarged module land 230, and heat exchanger 232, including vanes 236, are all formed of aluminum.

In addition, it is noted that arms 229 are inwardly curved, and define a cylindrical aperture 238, which receives and retains motor 218. This arrangement allows motor 218 to be mounted in aperture portion 238, below lower module land 230 and, thus, below module 212.

Some advantages provided by this location of the motor included easier assembly of the device 200, and allowing a greater range of shapes of the upper heat exchanger to be used.

In addition, relocating motor 218 below thermoelectric generator module 212, results in the airflow through the latter to be much greater as it is now in line with the most effective area of the sweep made by blades 240. This results in an increased temperature drop across module 212 and more power delivered to motor 218 and enhanced rotational speed of blades 240.

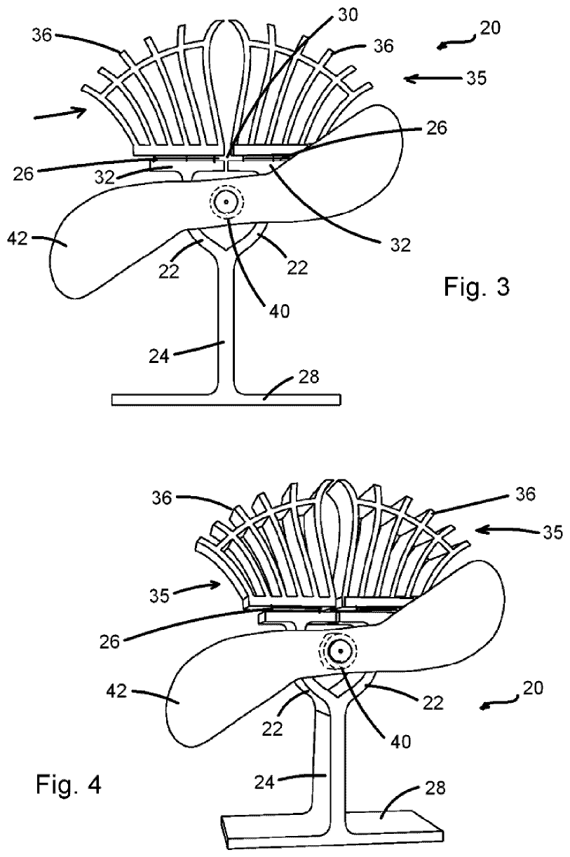

However, this approach provides the upper limits of what could be achieved using a single thermoelectric generator module, and thus, further improvements on these designs were desired. In accordance with the present invention, these improvements are now shown in FIGS. 3 to 6.

FIG. 3 is a front view of a fan assembly 20, according to the present invention, and FIG. 4 is a perspective view of the same fan assembly. In the approach of the present invention, heat transfer stem 24 meets with base 28 at a proximate end of stem 24. Stem 24 is joined to two arms 22, and the combined components provide a generally Y-shaped support structure. At the end of each of arms 22 are module lands 32.

Two thermoelectric generator modules 26 are provided on each of the module lands 32. A gap 30 is provided between modules 26 and module lands 32.

Motor 40 is positioned and attached to the fan assembly 20 in the area between inwardly curving arms 22. Fan blade 42 is connected to motor 40 (shown in outline only).

Two heat exchangers 35, with vanes 36, are thermally and physically attached to the other sides of each of modules 26. By providing two module lands 32, and two heat exchangers 36, two thermoelectric generator modules 26 can be used, wherein each module has its own heat exchanger 36 and module land 32. The two modules 26 are connected together in series (wires not shown).

In combination, these two modules 26 can easily provide increased surface area over the single thermoelectric generators of the prior art devices, and thereby can create additional electrical power over the earlier devices. Also, by use of gap 30, between the two module lands 32, heat related damage to modules 26 is essentially eliminated, when compared to the prior art device, since the present approach eliminates the need for the use of a single, larger single module land and a larger single thermoelectric generator module. As such, in the present approach, increased thermoelectric generator surface area is provided in a manner that is still resistant to heat damage.

In operation, the performance of fan assembly 20 was found to be superior to that of the device 100 or 200 of FIGS. 1, 2A and 2B.

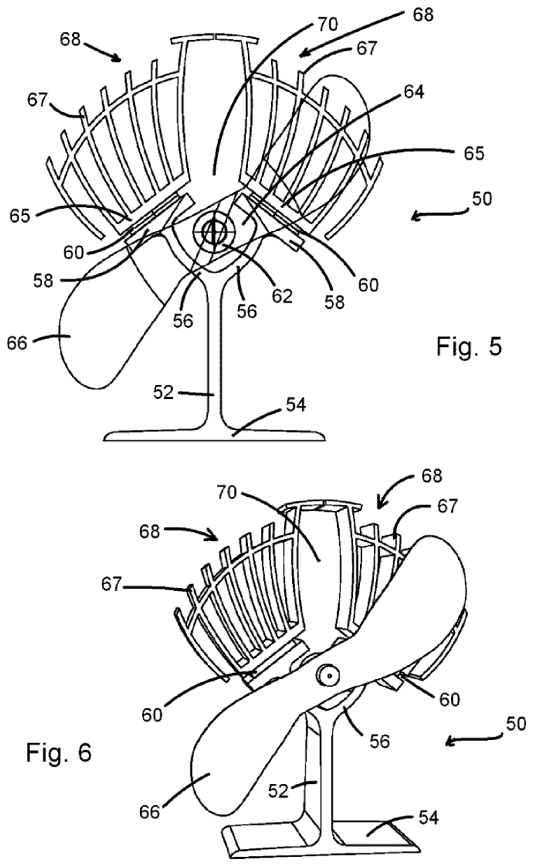

In FIGS. 5 and 6, a further embodiment of the present invention is shown. In this embodiment, fan assembly 50 includes heat transfer stem 52 which meets with base 54 at a proximate end of stem 52. Arms 56 are included at the distal end of stem 52 to provide a generally Y-shaped device. At the end of arms 56 are two heat transfer surface module lands 58 and two thermoelectric generator modules 60, which modules 60 are wired in series. Each module land 58 is thermally and physically attached to one side of one of thermoelectric generator modules 60.

Motor 62 is again positioned and attached to the fan assembly 50 in the area 64 between the two arms 56. Fan blade 66 is operatively connected to motor 62.

Two heat exchangers 68 are thermally and physically attached to the other sides of each of modules 60, and each has a base 65, and series of vanes 67. The heat exchangers 68 are mirror images of each other, and provide a symmetrical appearance to the device.

By providing two module lands 58, and two heat exchangers 68, the use of two thermoelectric generator modules 60, with an increased total module surface area, can be achieved. Thus, this approach allows two modules 60 to be used which provides increased surface area over the single thermoelectric generators of the prior art devices, and thereby can create additional electrical power over the earlier devices.

Gap 70 is located between the two module lands 58 so that the two modules 60 are again separated. However, in FIGS. 5 and 6, it will be clearly noted that the arms 56 are shorter than the corresponding features in FIGS. 3 and 4. Also, module lands 58 are angled at an angle of 120° with respect to each other. By shortening arms 56, and by angling module lands 58, the distance the heat has to travel through base 54, stem 42, and arms 56 is reduced. Also, by angling module lands 58, increased clearance is also provided for motor 62, while continuing to provide protection from radiant heat to the motor 62. Also, it can be noted that gap 70 in FIGS. 5 and 6 is clearly larger than the corresponding gap in FIGS. 3 and 4, which also allows for greater heat exchange area.

The approach shown in FIGS. 5 and 6 thus also allows the fan assembly 50 to include increased spacing in, around, and between heat exchangers 68, and/or for increased sizing of the heat exchangers 68. This provides a further increase in the effective cooling area swept by the movement of fan blades 66.

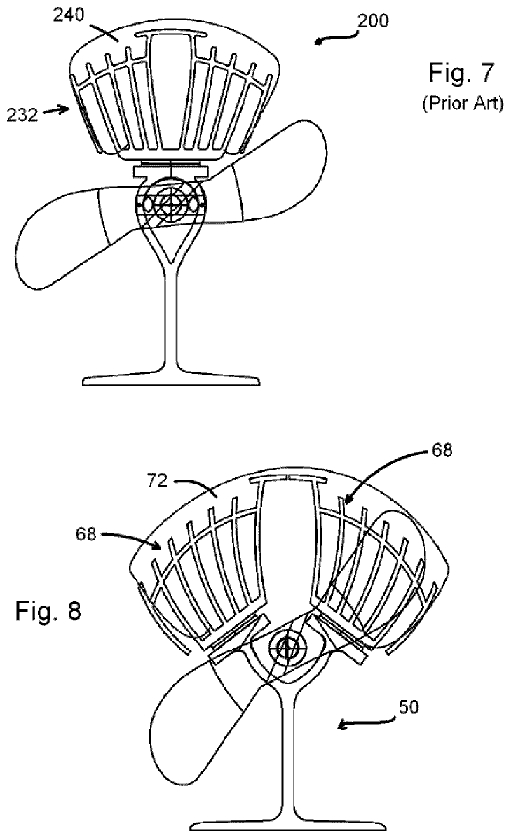

This effect is more clearly demonstrated in FIG. 7 and FIG. 8, wherein the areas 240 and 72 in FIGS. 7 and 8 respectively, represent the calculated effective cooling area of the heat exchanger 232, for the prior art device 200 shown in FIG. 2, and for the heat exchangers 68 for device 50, which are shown in FIG. 5. The device in FIG. 7 has a calculated effective cooling area 240, or surface area, of 104,980 square millimetres. The device in FIG. 8 has a calculated effective cooling area 72, or surface area, of 131827 square millimetres. As such, increased cooling of the upper surface of the two thermoelectric generator modules 60, as shown in FIG. 5, is provided, when compared to the single thermoelectric generator module 212 shown in FIG. 2A.

Moreover, since the heat path to the module lands 58 is shorter, and with less surface area in arms 56, more heat is delivered to the lower surface of thermoelectric generator modules 60. This combination results in a significant increase in electrical power, and airflow, while at the same time protecting the motor 62 and the thermoelectric generator modules 60 from overheating.

To demonstrate the improvement provided in the present invention, prototypes of the devices shown in FIGS. 7 and 8 were prepared and compared to each other. The tests were conducted on an electric hotplate to simulate a normal stovetop output. The equipment monitored temperatures, voltage and current and airflow. Selection of the materials of construction can be important since different materials can transfer the heat energy differently. For example, it should be noted that the prototypes were prepared from milled aluminum 6061, while the prior art devices were prepared from aluminum 6063 extrusions. Aluminum 6061 has a thermal conductivity of 167 W/m-K, and aluminum 6063 has a thermal conductivity of 200 W/m-K, or 1.2 times higher. Nonetheless, even with the lower heat transfer milled aluminum construction, it will be seen that the prototype of FIG. 8 outperformed the prior art device of FIG. 7.

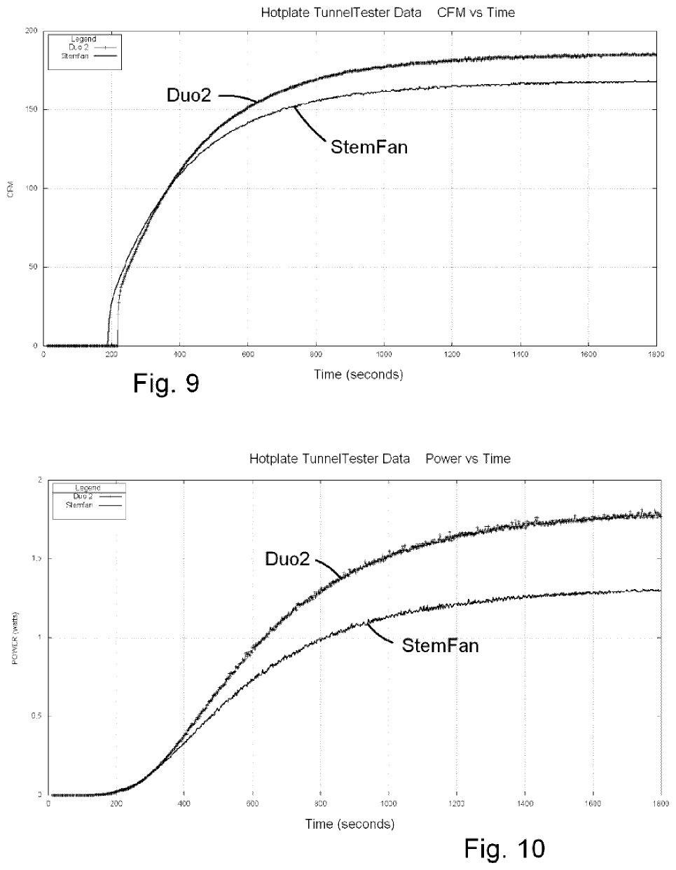

In FIG. 9, a comparison of the airflow from the prior art device of FIG. 7 (herein referred to as “Stemfan”) was compared against the device in FIG. 8 (hereinafter referred to as “Duo2”). Both devices were placed on a pre-heated hotplate, and the electrical power generated, and the resultant air movement caused by similar motors and fan blades, was recorded. In FIG. 9, it can be seen that the device of the present invention (Duo 2) clearly provided increased airflow in CFM (cubic feet per minute).

In FIG. 10, the electrical power from the two devices described in FIG. 9 is also shown. Again, it can be seen that the electrical power from the Duo2 device, of the present invention, is superior to the output power from the prior art Stemfan approach.

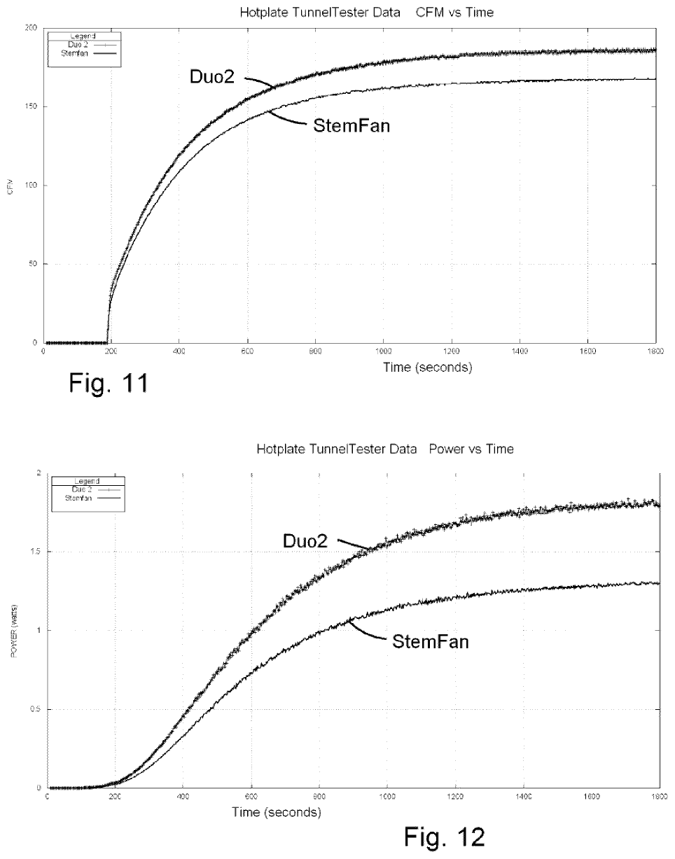

In FIGS. 11 and 12 the modules 60 in the Duo2 approach were wired in series and the fan blades were changed to better match the power output achieved in the Duo2 devices of the present invention. Under these conditions, using the original motor and fan blade tested in FIGS. 9 and 10, the Duo2 approach caused the prop to spin faster than could be safely operated as an open fan. As such, the fan blade used in the tests in FIGS. 11 and 12, had a deeper pitch to run slower. Even though the motor selected was not optimized for the fan blade, an increase in both airflow and power can be seen in FIGS. 11 and 12, with the fan blade operating at a safe speed. It can also be noted that the Duo2 approach of the present invention, started producing higher airflows sooner which is important on low temperature fires, and on cooler stoves such as soapstone and gas stoves.

As such, it is clear that the devices of the present invention provide improved performance over the prior art devices.

This disclosure has now described and illustrated certain preferred embodiments of the invention which are superior to the prior art devices. However, it is to be understood that the invention is not restricted to those particular embodiments shown in the figures. Rather, the invention includes all embodiments which are functional or mechanical equivalence of the specific embodiments and features that have been described and illustrated.

Thus, it is apparent that there has been provided, in accordance with the present invention, a self-powered thermal fan assembly which fully satisfies the goals, objects, and advantages set forth hereinbefore. Therefore, having described specific embodiments of the present invention, it will be understood that alternatives, modifications and variations thereof may be suggested to those skilled in the art, and that it is intended that the present specification embrace all such alternatives, modifications and variations as fall within the scope of the appended claims.

Additionally, for clarity and unless otherwise stated, the word “comprise” and variations of the word such as “comprising” and “comprises”, when used in the description and claims of the present specification, is not intended to exclude other additives, components, integers or steps. Further, the invention illustratively disclosed herein suitably may be practiced in the absence of any element which is not specifically disclosed herein.

Moreover, words such as “substantially” or “essentially”, when used with an adjective or adverb is intended to enhance the scope of the particular characteristic; e.g., substantially planar is intended to mean planar, nearly planar and/or exhibiting characteristics associated with a planar element.

Further, use of the terms “he”, “him”, or “his”, is not intended to be specifically directed to persons of the masculine gender, and could easily be read as “she”, “her”, or “hers”, respectively.

Also, while this discussion has addressed prior art known to the inventor, it is not an admission that all art discussed is citable against the present application.

1. A self-powered fan assembly for circulating air around a heating source, said fan assembly comprising:
a heat transfer stem thermally connected at a proximate end thereof with said heat source;
at least two heat transfer surface-containing arms connected to a distal end of said heat transfer stem;
module lands at each of the at least two arms so that each of said module lands are thermally connected to said arms, and thereby, to said heat transfer stem;
a gap defined between said module lands;
an electric motor to act as a fan motor which electric motor is attached to said fan assembly in an area between the at least two arms;
fan blades attached to said fan motor which blades are moved by said electric motor, and which operably create a warm air flow away from said fan, and a cooler air flow toward said fan;
at least two thermoelectric generator modules wherein each of said thermoelectric generator modules are individually thermally connected on a first surface to said module lands; and
a heat exchange structure which is thermally connected to a second, opposite surface of each of said thermoelectric generator modules,
whereby a heat gradient is created across each of the thermoelectric generator modules so as to generate electric power from each of said thermoelectric generator modules, and thereby power said fan motor.

2. A self-powered fan assembly as claimed in claim 1, wherein said fan has at least two heat exchange structures and each of said heat exchange structures is attached to the second, opposite surface of each of said thermoelectric generator modules.

3. A self-powered fan assembly as claimed in claim 1 wherein said electric motor is attached to said fan assembly in an area between the at least two arms.

4. A self-powered fan assembly as claimed in claim 1, wherein said heat transfer stem is both thermally and physically connected at a proximate end, to a base.

5. A self-powered fan assembly as claimed in claim 1, wherein said heat transfer stem is both thermally and physically connected at a proximate end thereof, with said heat source.

6. A self-powered fan assembly as claimed in claim 1, having two arms connected to said heat transfer stem, and each arm having a module land at an opposite end thereof, and having two thermoelectric generator modules which modules are individually attached to each module land.

7. A self-powered fan assembly as claimed in claim 6 wherein said heat transfer stem and said arms form a “Y” shaped device, with the lower end of the “Y” being the proximate end of said heat transfer stem, and the two upper ends of the Y-shaped heat transfer stem are two heat transfer surface-containing arms, which are each connected to one of said module lands.

8. A self-powered fan assembly as claimed in claim 7 wherein said module lands include a flat surface to which the thermoelectric generator module is thermally and physically attached.

9. A self-powered fan assembly as claimed in claim 8 wherein said module lands are coplanar with one another, in a side-by-side arrangement.

10. A self-powered fan assembly as claimed in claim 8 wherein the module lands are angled with respect to each other.

11. A self-powered fan assembly as claimed in claim 10 wherein said module lands are placed at an angle of between 60° and 150° with respect to each other.

12. A self-powered fan assembly as claimed in claim 10 wherein, the angles of the two module lands are in equal, but opposite directions, so that the module lands are positioned symmetrically across the device, and angled towards each other.

13. A self-powered fan assembly as claimed in claim 1 wherein said thermoelectric generator modules rely on the Seebeck Thermocouple Effect.

14. A self-powered fan assembly as claimed in claim 1 wherein said thermoelectric generator modules are wired, or otherwise electrically connected, in series.

15. A self-powered fan assembly as claimed in claim 1 wherein a single heat exchange structure is connected to all of said thermoelectric generator modules.

16. A self-powered fan assembly as claimed in claim 1 wherein a separate heat exchange structure is attached to each thermoelectric generator module.

17. A self-powered fan assembly as claimed in claim 1 wherein said the fan blade is oriented relative to the module lands so as to cause a portion of the ambient air flow to be drawn past the module lands, and thus provide a partial cooling effect on the module land.

18. A self-powered fan assembly as claimed in claim 1 wherein the axis of rotation of the fan is perpendicularly displaced, with respect to the surfaces of the thermoelectric generator modules and the heat exchange structure.

19. A self-powered fan assembly as claimed in claim 1 wherein heat exchange structures comprises vanes, and the vanes of the heat exchange structure are disposed, relative to the fan blades, so that the vanes extend through the cool air stream generated by the rotation of the fan blades.

20. A self-powered fan assembly as claimed in claim 1, in combination with a heat source, wherein said heat source is a fossil fuel burning devices which burns coal, oil or wood, or is a stove which operates by combustion of methane, propane or butane.

21. A heat source with a self-powered fan assembly, wherein said heat source is a fossil fuel burning devices which burns coal, oil or wood, or is a stove which operates by combustion of methane, propane or butane, and wherein said self-powered fan assembly is an assembly as claimed in claim 1 and having a proximate end of said heat transfer stem is formed into or permanently attached to said heat source.
